(19) United States
(12) Patent Application Publication
(10) Pub. No.: US 2026/0110612 A1
(43) Pub. Date: Apr. 23, 2026

(54) MEMS Resonator-Based Viscosimeter

(71) Applicant: Northeastern University, Boston, MA (US)

(72) Inventors: Luca Colombo, Boston, MA (US); Walter Gubinelli, Cambridge, MA (US); Pietro Simeoni, Boston, MA (US); Matteo Rinaldi, Boston, MA (US)

(21) Appl. No.: 19/363,403

(22) Filed: Oct. 20, 2025

Related U.S. Application Data
(60) Provisional application No. 63/709,519, filed on Oct. 20, 2024.

(51) Int. Cl. G01N 11/00; H03H 9/02; H03H 9/145

(52) U.S. Cl. CPC G01N 11/00; H03H 9/02543; H03H 9/02834; H03H 9/14502; G01N 2011/0073; G01N 2011/0093

(57) ABSTRACT

Provided herein is a surface acoustic wave resonator-based viscosimeter with capable of measuring viscosity and temperature of fluids at high temperatures. The viscosimeter utilizes interdigitated electrodes of a heat-resistant conductive metal disposed on a piezoelectric material. The resonance frequency and quality factor of the resonator vary with temperature and viscosity of the surrounding fluid, allowing both to be derived from measured resonator characteristics. The viscosimeter is capable of measuring and monitoring viscosity at temperature in the range from 500° C. to 900° C. and higher.

### CROSS REFERENCE TO RELATED APPLICATIONS

This application claims the priority of U.S. Provisional Application No. 63/709,519 filed 20 Oct. 2024 and entitled “A MEMS Resonator-Based Viscosimeter”, the whole of which is hereby incorporated by reference.

### BACKGROUND

The demand for high-performance sensing elements capable of operating in harsh environments is rapidly increasing across various fields, including industrial processing, environmental monitoring, and space exploration. These applications often rely on resonant sensors with high quality factors (Q), excellent frequency selectivity, and robust resistance to extreme conditions such as high temperatures, high pressures, corrosive chemicals, flames, and radiation [1].

Traditional sensing materials and devices often fail to meet the demands of harsh environments, particularly conventional thin-film devices that lack the required durability [2]. Furthermore, commonly used materials like aluminum are inadequate due to their low melting points and poor corrosion resistance [3]. Surface acoustic wave (SAW) sensors, while widely used due to their sensitivity and selectivity, face significant limitations in harsh conditions [4]. Despite their relatively high quality factors Q, at temperatures above 300° C., the electromechanical coupling kₜ² typically falls drastically, thus reducing their effectiveness in extreme environments [5].

Silicon carbide (SiC) electronics has emerged as a promising solution for high temperature operation, being capable of withstanding temperatures up to 800° C. [6]. However, the realization of SiC-compatible high figure of merit devices for harsh conditions still remains a substantial challenge [7].

### SUMMARY

The present technology provides a microelectromechanical systems (MEMS) resonator-based sensor designed to measure viscosity and temperature reliably in harsh environments, such as at high temperatures, in the presence of corrosive chemicals, or in conditions of intense physical stress. Traditional sensors often fail under such conditions due to material limitations. The present technology leverages certain piezoelectric materials, such as lithium niobate (LiNbO₃), known for their high piezoelectric coefficients and high Curie temperatures, combined with robust electrode materials such as gold and tungsten. This combination results in superior electromechanical coupling and quality factors, maintaining functionality even when exposed to direct flame at 900° C., for example. Using bulk leaky surface acoustic wave (LSAW) technology and resilient electrode materials, the present sensor overcomes the limitations of previous sensors and performs reliably in extreme conditions.

The sensor's capability has been demonstrated as a high temperature viscosimeter, consistently monitoring fluid viscosity with a stable temperature coefficient of frequency. The sensor not only addresses the durability issues of traditional sensors but also expands the capabilities of sensing technologies in harsh environments, benefiting industrial processing, monitoring of equipment performance, environmental monitoring, and space exploration.

An aspect of the present technology is a heat-resistant SAW resonator-based viscosimeter. The viscosimeter includes a piezoelectric layer comprising a piezoelectric material. The viscosimeter also includes a pair of interdigitated electrodes disposed on an upper surface of the piezoelectric layer, the interdigitated electrodes comprising a heat-resistant conductive metal, and each of the interdigitated electrodes linked via a heat-resistant conductive pathway to a contact pad or to a circuit component. When in contact with a fluid and connected via the conductive pathways to a readout circuit, the viscosimeter provides a signal indicating viscosity of the fluid at a high temperature of the fluid of, for example, at least 300° C., at least 500° C., at least 700° C., or at least 900° C.

The piezoelectric layer can be configured as a bulk solid or can contain a cavity below the upper surface of the piezoelectric layer. In some embodiments, the viscosimeter further comprise a substrate, wherein a lower surface of the piezoelectric layer opposite the interdigitated electrodes is disposed on a surface of the substrate.

The substrate can provide mechanical rigidity or a mechanical interface to other components of the sensor. The substrate can be configured as a bulk solid or can contain a cavity below its upper surface, i.e., below the interface between the substrate and the piezoelectric layer. In some embodiments, the viscosimeter further includes a mechanical layer, or second substrate layer, disposed below the first substrate. The mechanical layer optionally can include a cavity. if a cavity is present in the sensor, there is typically only one cavity, which can be included within the piezoelectric layer, within the substrate layer, or within the mechanical layer, or at the interface between any two layers. When a cavity is present, the device layers including the piezoelectric layer and the interdigitated electrodes may be released from the material above the cavity, and after release may be attached through one or more bridging portions, e.g., of the piezoelectric layer.

The piezoelectric material can be any piezoelectric layer having suitably high piezoelectric coefficient and Curie temperature. In some embodiments, the piezoelectric material is selected from lithium niobate, lithium tantalate, aluminum nitride, scandium doped aluminum nitride having a scandium content from about 1 mol % to about 45 mol %, and combinations thereof. In some embodiments, the piezoelectric material has a piezoelectric coefficient of at least 0.19 C/m². In some embodiments, the piezoelectric material has a Curie temperature of at least about 610° C., or at least about 650° C., at least about 700° C., at least about 750° C., at least about 800° C., at least about 850° C., or at least about 900° C. In some embodiments, the interdigitated electrodes comprise a metal or metal alloy selected from gold, tungsten, platinum, titanium, iridium, chromium, copper, and combinations thereof, wherein the metal or metal alloy has a melting temperature of at least 300° C., at least 500° C., at least 700° C., or at least 900° C. In some embodiments, the substrate comprises silicon, silicon carbide, diamond, sapphire, or a combination thereof. In some embodiments, the piezoelectric layer has a thickness from about 100 nm to about 525 μm, the interdigitated electrodes have a thickness from about 20 nm to about 10 μm, and the substrate, if present, has a thickness from about 100 μm to about 780 μm, the interdigitated electrodes have a pitch from about 20 nm to about 500 μm, and an aspect ratio from about 0.01 to about 1.0.

In some embodiments, a ratio between an acoustic wavelength (λ), a thickness of the interdigitated electrodes (tₑₗ), and a metallization ratio (c) is sized to ensure maximization of the product between the quality factor and the electromechanical coupling. In some embodiments, the fluid is a liquid or a gas. In some embodiments, the SAW resonance mode comprises Rayliegh waves, Lamb waves, Love waves, Sezawa waves, or an overtone thereof. In some embodiments, a quality factor at resonance or antiresonance exhibits dependence on temperature and viscosity of said fluid. In some embodiments, the dependence on temperature is characterized by a temperature coefficient of frequency from about-10 ppm/K to about +10 ppm/K. In some embodiments, the dependence on viscosity is characterized by a viscoelastic damping quality factor of at least about 1000.

In some embodiments, the viscosimeter has an electromechanical coupling from about 1% to about 50%. In some embodiments, the viscosimeter has a quality factor of at least about 1000 in the absence of fluid and at about 15° C. to 40° C. In some embodiments, the viscosimeter has a figure of merit of at least about 300. In some embodiments, the viscosimeter has a power handling capacity of up to at least 15 dBm. In some embodiments, the viscosimeter further comprises a readout circuit connected via the contact pads to the pair of interdigitated electrodes and a battery driving the readout circuit. In some embodiments, the viscosimeter further comprises a wired or wireless transmitter or transponder, and/or a display.

In a further aspect, a system for detecting viscosity is provided. The system includes at least one processor, at least one memory, a microcontroller, and one or more viscosimeters of any of the preceding embodiments deployed in an environment having a viscosity of interest. In some embodiments, the system further comprises a reader device for wireless communications with the one or more viscosimeters. In some embodiments, the system further comprises an internal combustion engine, hydraulic machine, chemical processing plant or refinery, or rocket engine in which the one or more viscosimeters are deployed.

In still another aspect, a method for determining a viscosity of a fluid is provided. The method includes providing, a viscosimeter of any of the previous embodiments, or the system of any of the previous embodiments. The method includes contacting the viscosimeter with said fluid. The method further includes establishing an AC signal across the interdigitated electrodes of the viscosimeter, whereby a SAW resonance is produced in the viscosimeter. The method further includes measuring a resonance frequency of the MEMS resonator of the viscosimeter or the system. The method further includes determining the viscosity of the fluid based on the resonance frequency.

The present technology also can be summarized with the following list of features.
1. A heat-resistant surface acoustic wave (SAW) resonator-based viscosimeter comprising:
   a piezoelectric layer comprising a piezoelectric material;
   a pair of interdigitated electrodes disposed on an upper surface of the piezoelectric layer, the electrodes comprising a heat-resistant conductive metal, each of said electrodes linked via a heat-resistant conductive pathway to a contact pad;
wherein the viscosimeter supports a surface acoustic wave (SAW) mode of resonance;
wherein the viscosimeter, when in contact with a fluid and connected via the contact pads to a readout circuit, provides a signal indicating viscosity of the fluid at a temperature of the fluid of at least 500° C., at least 700° C., or at least 900° C.
2. The viscosimeter of feature 1, wherein the piezoelectric layer is a bulk solid or comprises a cavity below the upper surface of the piezoelectric layer.
3. The viscosimeter of feature 1, further comprising a substrate, wherein a lower surface of the piezoelectric layer opposite the electrodes is disposed on a surface of the substrate.
4. The viscosimeter of feature 1, wherein the substrate is solid or comprises a cavity below the piezoelectric layer.
5. The viscosimeter of feature 3, further comprising a second mechanical layer disposed below the substrate, the second mechanical layer optionally comprising a cavity.
6. The viscosimeter of any of the preceding features, wherein the viscosimeter comprises a cavity in the piezoelectric layer or in the substrate, and wherein a portion of the piezoelectric layer and/or the substrate layer above the cavity is released.
7. The viscosimeter of any of the preceding features, wherein the piezoelectric material is selected from the group consisting of lithium niobate, lithium tantalate, aluminum nitride, scandium doped aluminum nitride having a scandium content from about 1 mol % to about 45 mol %, and combinations thereof.
8. The viscosimeter of any of the preceding features, wherein the piezoelectric material has a piezoelectric coefficient of at least 0.19 C/m².
9. The viscosimeter of any of the preceding features, wherein the piezoelectric material has a Curie temperature of at least 610° C.
10. The viscosimeter of any of the preceding features, wherein the electrodes comprise a metal or metal alloy selected from the group consisting of gold, tungsten, platinum, titanium, iridium, chromium, copper, and combinations thereof, wherein the metal or metal alloy has a melting temperature of 300, 500, 700, or 900° C.
11. The viscosimeter of any of the preceding features, wherein the substrate comprises silicon, silicon carbide, diamond, sapphire, or a combination thereof.
12. The viscosimeter of any of the preceding features, wherein the piezoelectric layer has a thickness from about 100 nm to about 525 μm, the electrodes have a thickness from about 20 nm to about 10 μm, and the substrate, if present, has a thickness from about 100 μm to about 780 μm, the electrodes have a pitch from about 20 nm to about 500 μm, and an aspect ratio from about 0.01 to about 1.0.
13. The viscosimeter of any of the preceding features, wherein the ratio between the acoustic wavelength (λ), the thickness of the electrodes (tₑₗ), and the metallization ratio (c) is sized to ensure the maximization of the product between the quality factor and the electromechanical coupling.
14. The viscosimeter of any of the preceding features, wherein the fluid is a liquid or a gas.
15. The viscosimeter of any of the preceding features, wherein the SAW resonance mode comprises Rayliegh waves, Lamb waves, Love waves, Sezawa waves, or an overtone thereof.
16. The viscosimeter of any of the preceding features, wherein a quality factor at resonance or antiresonance exhibits dependence on temperature and viscosity of said fluid.
17. The viscosimeter of feature 16, wherein said dependence on temperature is characterized by a temperature coefficient of frequency of from about −10 to about +10 ppm/K.
18. The viscosimeter of feature 16 or 17, wherein said dependence on viscosity is characterized by a viscoelastic damping quality factor of at least about 1000.
19. The viscosimeter of any of the preceding features, having an wherein the viscosimeter has an electromechanical coupling of from about 1% to about 50%.
20. The viscosimeter of any of the preceding features, wherein the viscosimeter has a quality factor of at least about 1000 in the absence of fluid and at about 15 to 40° C.
21. The viscosimeter of any of the preceding features, wherein the viscosimeter has a figure of merit of at least about 300.
22. The viscosimeter of any of the preceding features, wherein the viscosimeter has a power handling capacity of up to at least 15 dBm.
23. The viscosimeter of any of the preceding features, further comprising a readout circuit connected via the contact pads to the pair of interdigitated electrodes and a battery driving the circuit.
24. The viscosimeter of feature 23, further comprising a wired or wireless transmitter or transponder, or a display.
25. A system for detecting viscosity, comprising:
   at least one processor;
   at least one memory;
   a microcontroller; and
   one or more viscosimeters of any of the preceding features deployed in an environment having a viscosity of interest.
26. The system of feature 25, further comprising a reader device for wireless communications with the one or more viscosimeters.
27. The system of feature 25 or 26, further comprising an internal combustion engine, hydraulic machine, chemical processing plant or refinery, or rocket engine in which the one or more viscosimeters are deployed.
28. A method for determining a viscosity of a fluid, the method comprising:
   (a) providing a viscosimeter of any of features 1-24, or the system of any of features 25-27, wherein the viscosimeter contacts said fluid;
   (b) establishing an AC signal across the interdigitated electrodes of the viscosimeter, whereby a SAW resonance is produced in the viscosimeter;
   (c) measuring a resonance frequency of the viscosimeter;
   viscosity of the fluid using the viscosimeter or the system; and
   (d) determining said viscosity based on the resonance frequency.
29. The method of feature 28, further comprising:
   (e) displaying or transmitting to a receiver the viscosity determined in step (d).
30. The method of feature 28 or 29, further comprising: measuring a temperature of the fluid using the viscosimeter.
31. The method of any of features 28-30, wherein the fluid is liquid or a gas.
32. The method of any of features 28-31, wherein the temperature of the fluid is at least 500° C., at least 700° C., or at least 900° C.
33. The method of any of features 28-32, wherein the viscosimeter is disposed in an internal combustion engine, hydraulic machine, chemical processing plant or refinery, or rocket engine.
34. The method of any of features 28-33, wherein the fluid is an oil, lubricant, hydraulic fluid, fuel, or transmission fluid.
35. The method of any of features 28-34, further comprising:
   comparing the measured viscosity to reference viscosity data for said fluid; and
   determining a state of contamination for the fluid.

### BRIEF DESCRIPTION OF THE DRAWINGS

FIGS. 1A-1E illustrate alternative material configurations for the MEMS resonator-based viscosimeter, in accordance with several embodiments.

FIG. 2A illustrates computed electromechanical coupling kt2(16) in X, Y, and Z directions as function of Euler angles in lithium niobate. FIG. 2B illustrates kt2(16) for commercially available lithium niobate cuts. FIG. 2C-1 is a scanning electron microscope (SEM) image of a fabricated viscosimeter embodiment of the present technology. FIG. 2C-2 shows a schematic illustration of an embodiment of interdigital electrodes used in which W electrodes were overlaid with Au. FIG. 2C-3 illustrates COMSOL® simulated mode shape of a SAW at the electrodes of the viscosimeter shown in FIG. 2C-1. FIG. 2D illustrates the COMSOL® simulated electromechanical coupling constant as a function of normalized metal thickness tₘ/λ on X-cut lithium niobate, for electrode metals tungsten (top), platinum (middle), and gold (bottom). FIG. 2E illustrates COMSOL® simulated electromechanical coupling as a function of normalized metal thickness tₘ/λ of electrodes on Y-cut lithium niobate. FIG. 2F illustrates COMSOL® simulated electromechanical coupling as function of normalized metal thickness tₘ/λ of electrodes on Z-cut lithium niobate.

FIG. 3A illustrates measured through transmittance for gold fabricated devices with corresponding mBVD fitting, highlighting FOM=294 at fₛ=433.7 MHz. FIG. 3B illustrates measured through transmittance for tungsten fabricated devices with corresponding mBVD fitting, highlighting FOM=166 at fₛ=546.2 MHz. FIG. 3C illustrates power handling measurements from +10 dBm to +20 dBm for the gold fabricated devices. FIG. 3D illustrates power handling measurements from +10 dBm to +20 dBm for the tungsten fabricated devices.

FIG. 4A illustrates measured frequency shift for gold fabricated devices for temperatures spanning from T=20° C. to T=200° C. FIG. 4B illustrates measured frequency shift for tungsten fabricated devices for temperatures spanning from T=20° C. to T=200° C. FIG. 4C illustrates extracted and fitted Temperature Coefficient of Frequency for both the gold and tungsten fabricated devices. FIG. 4D illustrates and ultimate survivability test up to T=900° C. for gold fabricated devices.

FIG. 5A illustrates a schematic illustration of an experimental setup for viscosity measurements using a viscosimeter. FIG. 5B illustrates measured resonance impedance Rₛ and loaded quality factor Qₛ with and without oil damping for a gold fabricated device. FIG. 5C illustrates measured resonance impedance Rₛ and loaded quality factor Qₛ with and without oil damping for a tungsten fabricated device. FIG. 5D illustrates the effect of temperature (and consequently viscosity) on extracted viscosity quality factor for both gold and tungsten fabricated devices, highlighting the consistency between the two measurements.

### DETAILED DESCRIPTION

The present technology provides a MEMS resonator-based sensor designed to measure viscosity and temperature at high temperatures in the range of 500° C. to 900° C. and higher. The sensor device is also resistant to corrosive chemicals and high physical stress. The sensor device utilizes select piezoelectric materials having high piezoelectric coefficients and high Curie temperatures. The metallic components including the device electrodes or transducers as well as conductive pathways and contacts are fabricated from robust materials such as gold, platinum, or tungsten. The devices have high electromechanical coupling and quality factors, even at high temperatures such as 900° C.

The present devices can be configured as viscosimeters, thermometers, or a combination of the two measuring both viscosity and temperature at high temperature conditions. The temperature coefficient of frequency (TCF) is intrinsic to both the materials used and the resonator embodiment. This means that any change in temperature will result in a change in frequency according to the TCF coefficient. This per se configures the sensor as a thermometer. If the resonator is then exposed to a fluid with a viscosity that changes according to certain parameters, the change in viscoelastic damping can be measured through the sensor, i.e., the sensor works as a viscosimeter. In an application in which the viscosity changes because of temperature, a second independent temperature sensor (which could be an off-the-shelf temperature probe) is necessary to perform a differential measurement to separate the temperature dependency (TCF) to the viscosity dependency (Qₑₜₐ). In another application in which the viscosity changes under constant temperature by other factors (i.e. shear rate), the sensor can work as a stand-alone viscosimeter.

In a preferred embodiment, the device is a microacoustic shear horizontal leaky surface acoustic wave (LSAW) sensor capable of measuring both viscosity and temperature at 900° C. or higher and having a lithium niobate piezoelectric layer, selected for its high piezoelectric coefficient and Curie point of 1140° C. The device also has gold or tungsten interdigitated electrodes, optionally also including a pair of Bragg reflectors composed of the same metal, and achieving high electromechanical coupling (k²t) and quality factor (Q), whose product or figure of merit (FOM) is up to 300 or more. It also handles power levels up to 20 dBm or higher. Bragg reflectors can optionally be added to enhance acoustic energy confinement and boost quality factors. Additionally, compared to traditional SAWs, shear horizontal SH₀ leaky SAWs (LSAWs) can be used to obtain larger figures of merit with a wider range of stability [9].

For a sensor device configured to measure both viscosity and temperature, the relationship between the quality factor (Qη), fluid viscosity (η), and temperature (T) is given by Qη∝1/η∝T. This allows the sensor to accurately infer both temperature and viscosity changes in the surrounding environment of the sensor.

The resonant mode exhibited by the resonator can be a SAW mode, including Rayleigh waves, Love waves, Sezawa waves, or Lamb waves, or an overtone any of these modes. The resonant mode should have a high dependency between a quality factor at resonance (Qs) and anti-resonance (Qp), the environment's temperature (manifested as a temperature coefficient of frequency >10 ppm/K), and viscosity through the viscoelastic damping coefficient.

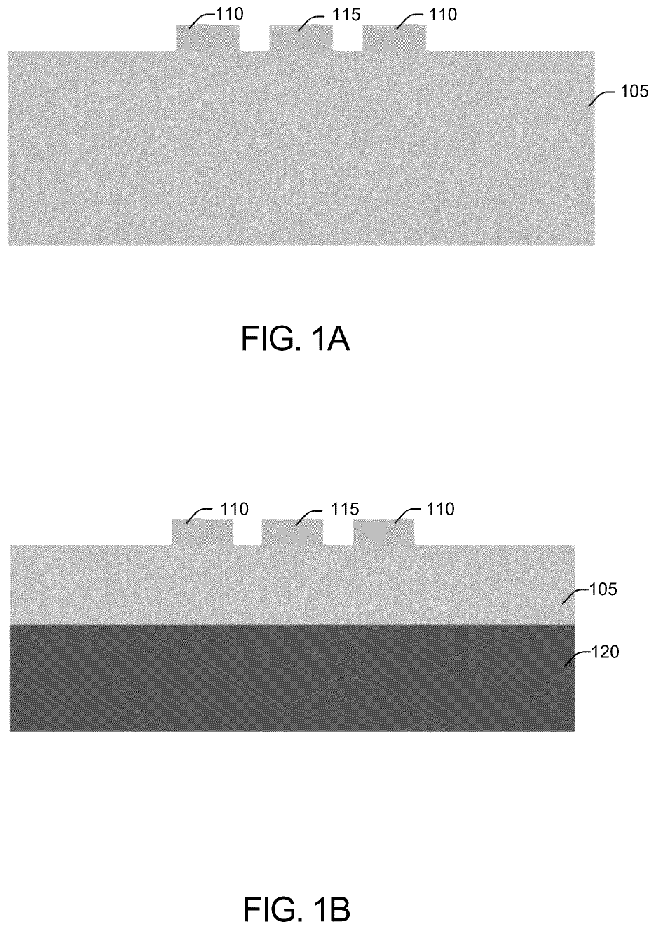

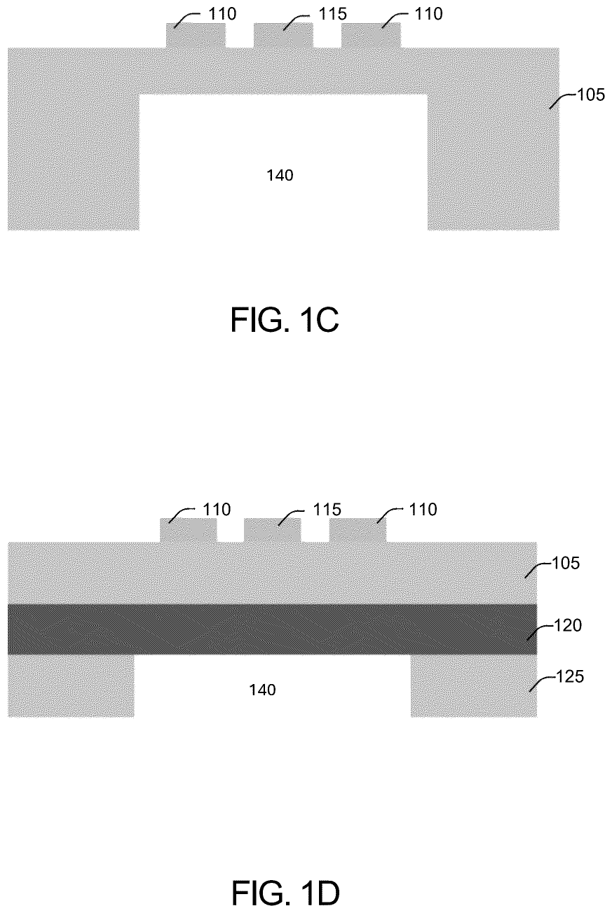

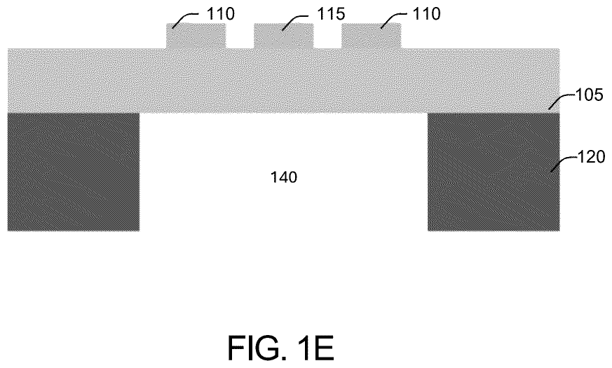

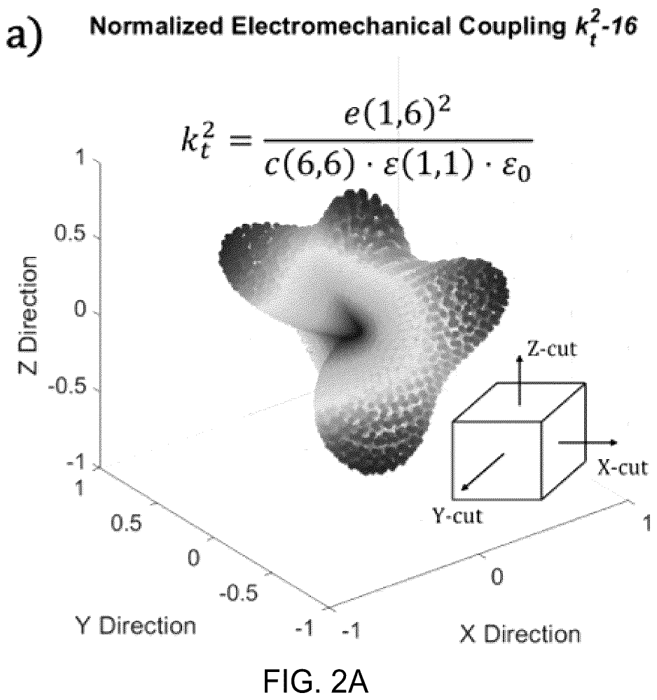

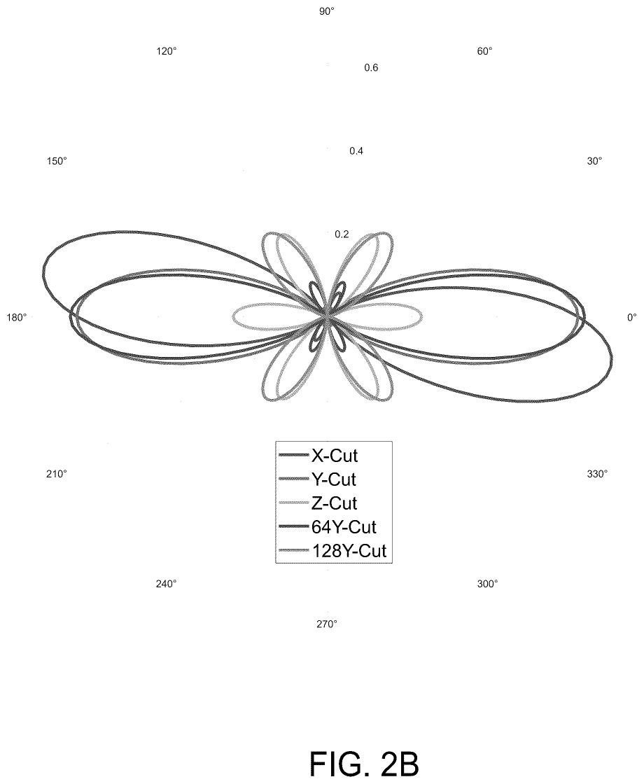

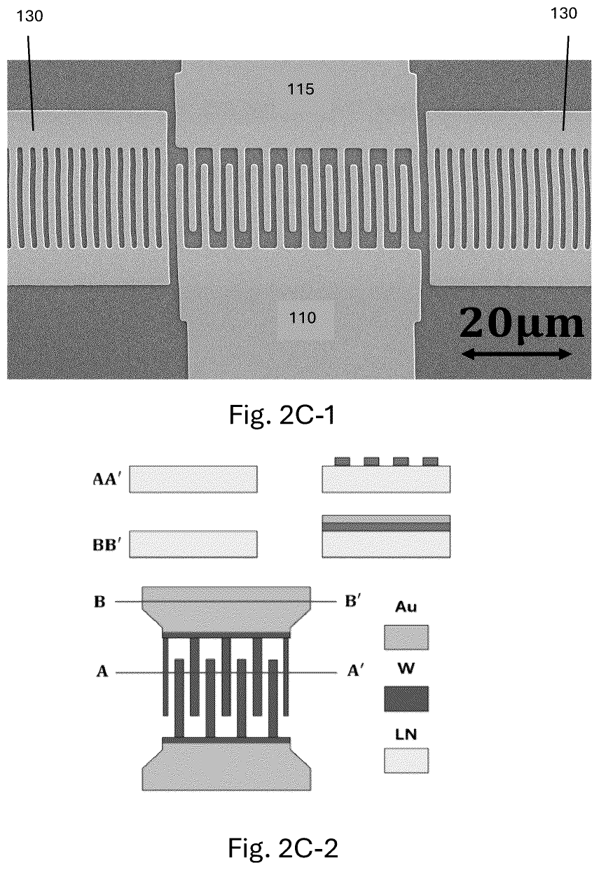

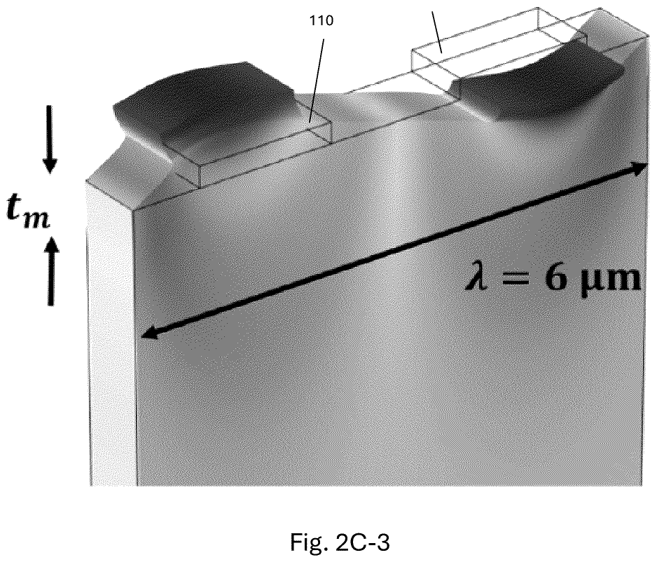

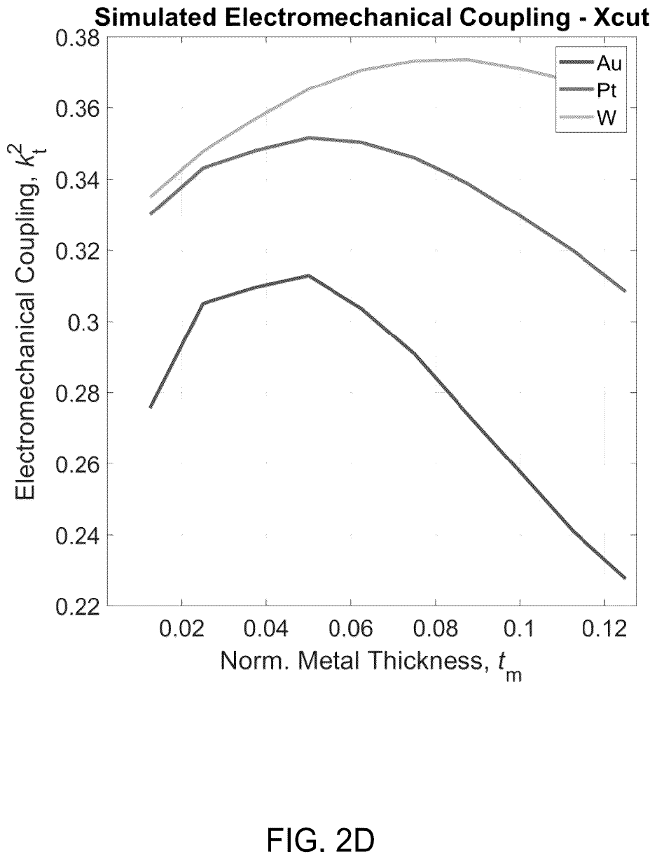

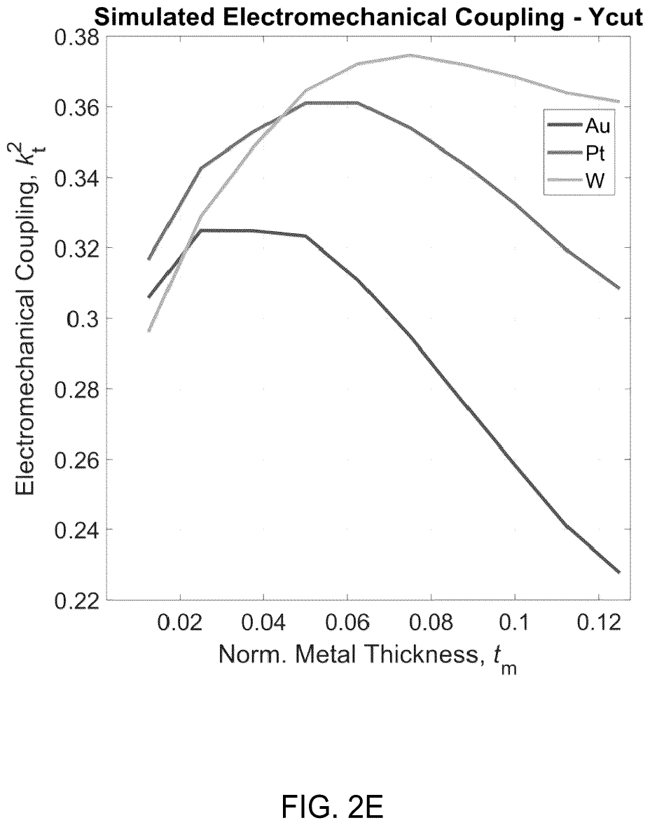

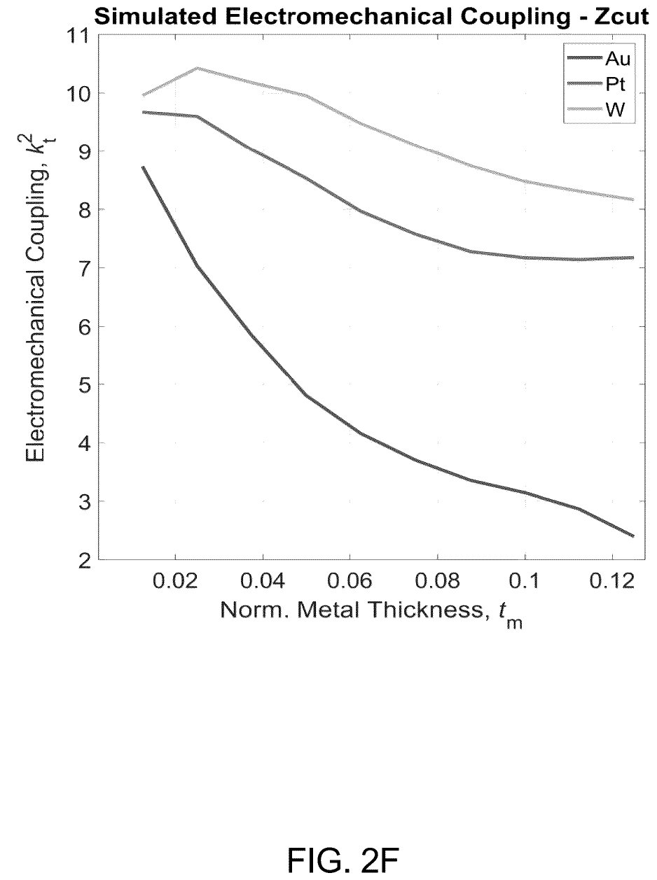

FIGS. 1A-1E illustrate several alternative configurations for the MEMS resonator-based viscosimeter, in accordance with different embodiments. FIG. 1A shows a cross-sectional view of an embodiment of the MEMS resonator-based viscosimeter comprising piezoelectric layer 105 with first and second interdigitated electrodes 110 and 115 disposed on the piezoelectric layer 105. The electrodes are shown in cross-section, and an embodiment of their two-dimensional top view configuration can be seen in FIG. 2C-1. FIG. 1B shows a cross-sectional view of another embodiment of the MEMS resonator-based viscosimeter which is similar to that shown in FIG. 1A, but with the addition of substrate 120 below piezoelectric layer 105. FIG. 1C shows a cross-sectional view of another embodiment of the MEMS resonator-based viscosimeter, which is similar to that shown in FIG. 1A but with the addition of cavity 140 within the piezoelectric layer. The presence of the cavity changes the resonance properties of the resonator, and in such cases the resonating elements of the device, namely the upper portion of the piezoelectric layer above the cavity and the electrodes deposited thereupon, can be released from the rest of the piezoelectric layer, retaining one or more, such as a pair, of connecting bridges between the piezoelectric layer and the released portion of the device. FIG. 1D shows a cross-sectional view of another embodiment of the MEMS resonator-based viscosimeter which is similar to the embodiment shown in FIG. 1C in that it includes cavity 140, but wherein the cavity is formed beneath substrate 120 by the addition of mechanical (or second substrate) layer 125, which surrounds and forms the cavity. This provides different mechanical and resonance properties compared to the device depicted in FIG. 1C. FIG. 1E shows a cross-sectional view of an embodiment of the MEMS resonator-based viscosimeter which is similar to the device depicted in FIG. 1B, but wherein the substrate layer includes cavity 140. This can produce still different mechanical and resonance properties compared to the other depicted devices.

The piezoelectric layer 105 of the MEMS resonator-based viscosimeter can be formed entirely from, or can contain any piezoelectric material that has a sufficiently high Curie temperature and electromechanical coupling coefficient. Examples of suitable materials include lithium niobate, lithium tantalate, aluminum nitride, and scandium doped aluminum nitride with a Sc concentration ranging from 1% to 45%. The substrate 120 of the MEMS resonator-based viscosimeter can be one of lithium niobate, silicon, silicon carbide, diamond, or sapphire. The MEMS resonator-based viscosimeter comprises materials that have sufficient resistance to the high temperatures and corrosive environments in which they are intended to operate.

The crystal orientation of the piezoelectric material affects its electrical, mechanical, and piezoelectric properties. Any of the commercially available orientations of LN (X-cut, Y-cut, Z-cut, 128Y-cut, 36Y-cut, 64Y-cut etc.) can be used in the present technology, though X-cut is just the most common. Referring to FIG. 2B, irrespectively of the cut used, if one wants to use a leaky SAW material that leverages 16 coupling, the device orientation must use an adequate crystal orientation that maximizes the coefficient. For instance, a device oriented at 90 on an X-cut wafer would not support 16 Rayleigh waves. If one wants to utilize other modes, such as SAW modes, the device orientation must follow a direction that maximizes the corresponding electromechanical coupling. The “thin layer of piezoelectric above a susbtrate” case is covered in your previous claim, when you talk about Sezawa modes (that are piezo on insulator) or ScAlN/AlN on Silicon Lithium niobate and lithium tantalate are grown as Z-cut, then the wafers are obtained by properly orienting the crystal during the slicing. AlN/ScAlN orientations are both c-axis oriented, the quality of the film is controlled by proper choice of material substrate and growth condition.

The interdigitated electrodes can be formed entirely from or contain (form part of an alloy containing) a material compatible with harsh environmental operations, such as gold, tungsten, platinum, titanium, iridium, chromium, or a combination of such materials (e.g., gold-tungsten).

Fabrication of sensor devices according to the present technology can be carried out using standard microfabrication techniques. In the embodiment exemplified hereinbelow, fabrication can be carried out starting from a bulk X-cut lithium niobate wafer. The metal layer can be deposited by means of either electron beam evaporation, thermal evaporation, or magnetron sputtering. The interdigitated electrodes can be then patterned by means of photolithography and etched by means of Ion Beam Etching (IBE). Other etching technologies, such as Reactive Ion Etching (RIE) could be used to pattern the metal layer. In some embodiments, electrodes could be patterned by means of a liftoff process (i.e., metal deposition on top of a patterned photoresist). In some embodiments, a thin film piezoelectric layer (such as aluminum nitride or scandium doped aluminum nitride) is grown by means of reactive radio frequency magnetron sputtering or pulsed laser deposition. In some embodiments, thin layers of piezoelectric material such as lithium niobate or lithium tantalate can be layered on top of insulating materials (e.g. silicon, silicon carbide, sapphire, diamond) by means of film transfer technologies. In some embodiments, cavities can be opened below the piezoelectric layer by means of selective chemical etching such as xenon difluoride or vapor hydrofluoric acid dry etching.

As shown in FIG. 2C-2, the interdigitated electrodes can be considered at two cross-sections, AA′ and BB′. Section AA′ represents the interdigitated fingers, which can be composed of, for example, either Au or W in the viscosimeter embodiments exemplified below. An alternative configuration, also within the present technology, employs layering of two different metals, for example, W+Au, in the electrode fingers themselves, to boost performance. Cross-section BB′ represents the electrodes used to provide the voltage difference to the fingers (i.e., the contact pads). This configuration was used because it can be harder to wire bond or probe the pads if they were also composed of W, but the overlay of W with Au is optional. Resonators also can be constructed using entirely Au for the electrodes, in which case no overlay with another metal is needed. Both Au and W electrodes were investigated, both for their performance in harsh environment sensing, and to cross-validate the measurements.

The IDE configuration can be such that the ratio between the acoustic wavelength (λ) and the thickness of the electrode material (tₑₗ) are sized so as to ensure the maximization of the quality factor, and hence the highest impact of viscoelastic damping on the measurement. The ratio tₑₗ/λ is a function of the material, or the stacking of materials, selected for the sensing element of the device (i.e., the electrodes, piezoelectric material layer, and any lower layers in the stack that affect the mode or frequency of resonance). In a case of a heterogeneous/layered structure, the piezoelectric film thickness and the additional layers may be selected to maximize the sensing element performance around the resonant frequency of interest.

Redout circuits can be used to set up and measure vibration modes and frequencies for the sensors of the present technology. Readout circuits generally can be realized by means of available off-the-shelf electronic components. These may or may not include the following components: one or more inductors, capacitors, oscillators, transformers, operational amplifiers, transistors, filters, magnetic flux coils, diodes, wireless antennas, and the like. The readout system must be capable of tracking both the resonator's frequency shifts and quality factor variations. The readout system may be connected to the resonant device either through wired or wireless methods. This could be achieved by means of any combination of the above specified components in addition to signal processing techniques or wireless RF interrogation methods, such as chirp-and-listen, and others known in the art.

The MEMS resonator-based viscosimeter may be connected to or incorporated into a computing system comprising at least one processor and memory. The computing system may include a screen or is connected to a screen that is capable of displaying measurement data generated by the MEMS resonator-based viscosimeter. The connection between the MEMS resonator-based viscosimeter and the computing system may be wired or wireless. In a wireless configuration, the MEMS resonator-based viscosimeter may include a transmitter or transponder capable of transmitting measurement data via a wireless protocol (e.g., Wi-Fi, Bluetooth, etc.) to one or more receivers, such as the computing system.

LSAWs have much larger electromechanical coupling than traditional SAWs and are therefore preferred. However, because the mode is largely localized in the electrodes themselves, LSAWs are more sensitive to viscoelastic damping than SAWs. LSAWs and SAWs are obtained essentially in the same way, by patterning electrodes on top of a bulk piezoelectric material. The two key differences are that SAWs use kt2(11) and LSAWs use kt2(16)). For a given lambda, SAW Rayleigh modes can be obtained for thinner metal layers, whereas LSAWs typically need thicker metal layers to confine the mode. SH₀ LSAW primarily exploits kₜ_{₁₆}², which is significantly higher for many available lithium niobate cuts as shown in FIGS. 2A & 2B. However, not all configurations can support leaky waves with high coupling, as specific combinations electrodes materials and thicknesses are necessary to achieve high performance [10]. As described herein, lithium niobate SH₀ LSAWS are optimized for several commercially available cuts (e.g., X-cut, Y-cut, Z-cut) and electrode materials (e.g., gold, platinum, tungsten) via COMSOL® finite element analysis. Simulated kₜ² as a function of normalized metal thickness tₘ/λ are reported in FIGS. 2D-2F for X, Y, and Z-cut, respectively. According to simulations, tungsten is supposed to yield the best performance for both coupling and quality factor due to superior acoustic energy confinement close to the piezoelectric surface.

For functional characterization, MEMS resonators were fabricated using standard microfabrication process employing a bulk X-cut lithium niobate wafer. Alternatively, thin films of the piezoelectric material (e.g., lithium niobate or lithium tantalate) can be layered on top of an insulating substrate by means of film transfer

The chosen metals for these studies were gold (Au) and tungsten (W). The interdigitated transducer (IDT) structure was lithographically defined around a fixed λ of 6 μm, with different combinations of aperture length, number of fingers, and Bragg reflector spacing. The Bragg reflectors were employed in shorted configuration to further confine acoustic energy in the IDT region, boosting the quality factor. In general, reflectors are patterned outside the resonant body and not connected to the driving signal. They can be in either open configuration (meaning that each finger is standalone) or shorted configuration (meaning that all fingers are connected through a bus). The fabrication process consisted of two lithographic steps to fabricate both W and Au+W devices on the same wafer. The W layer was deposited via RF magnetron sputtering and was patterned via lift-off, with a thickness of 230 nm. The Au layer was deposited via e-beam evaporation with a thickness of 300 nm, thus defining the set of electrodes used for testing Au overlay of W at the contact pads. Using the same mask, gold pads were overlapped over the existing tungsten structures to reduce contact resistance during probing. The wafer was then diced and preliminary characterization was performed using direct RF probing in combination with a Vector Network Analyzer.

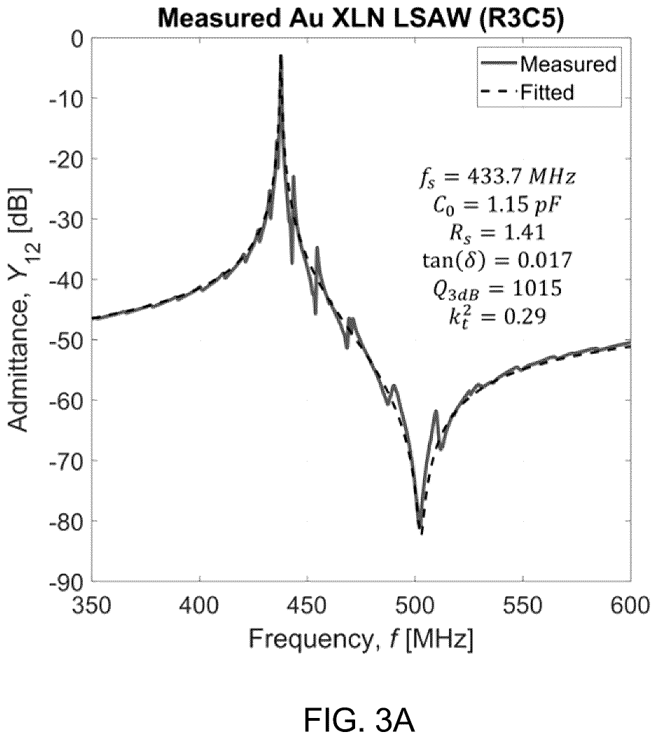

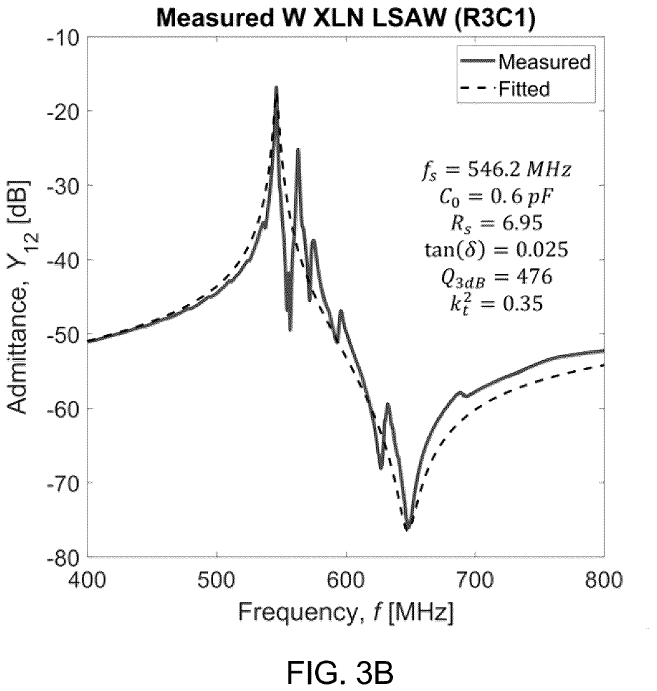

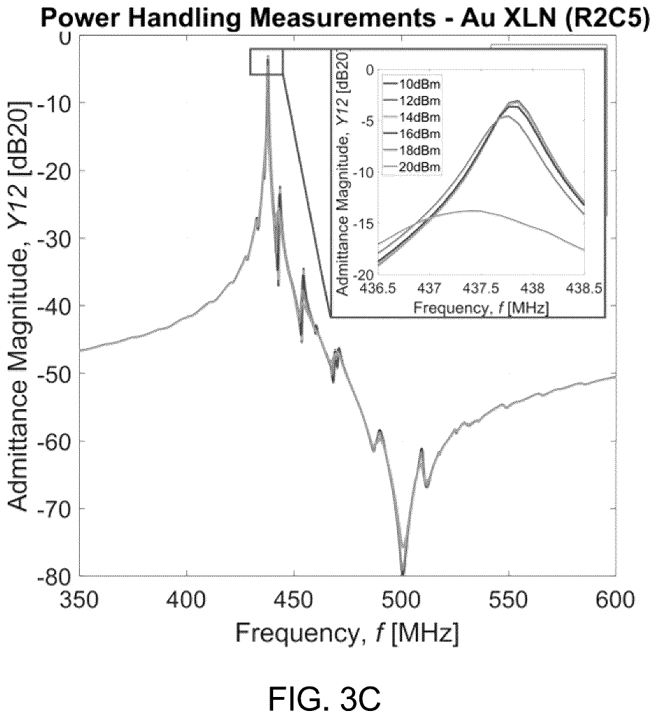

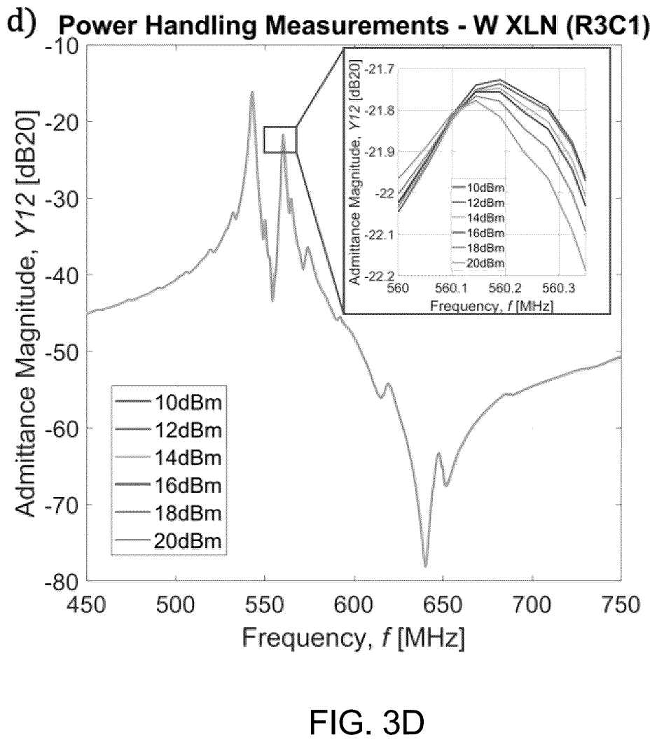

The measured scattering parameters were then converted to admittance Y₁₂ for processing. The devices were fitted via single-tone mBVD model, as shown in FIGS. 3A & 3B. As simulated, tungsten devices showed larger electromechanical coupling kₜ², but lower quality factor, as limited by various loss mechanisms in the metal [10]. Power handling measurements were carried out via RF probing; the results are shown in FIGS. 3C & 3D. Au devices showed good stability up until 15 dBm, whereas tungsten LSAWs did not show substantial degradation up to 20 dBm, attesting to the exceptional resilience of the metal.

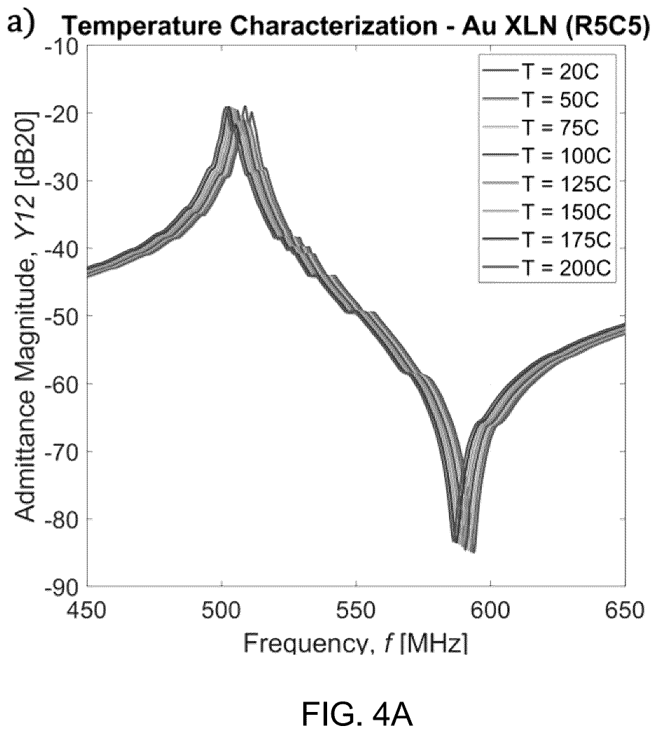

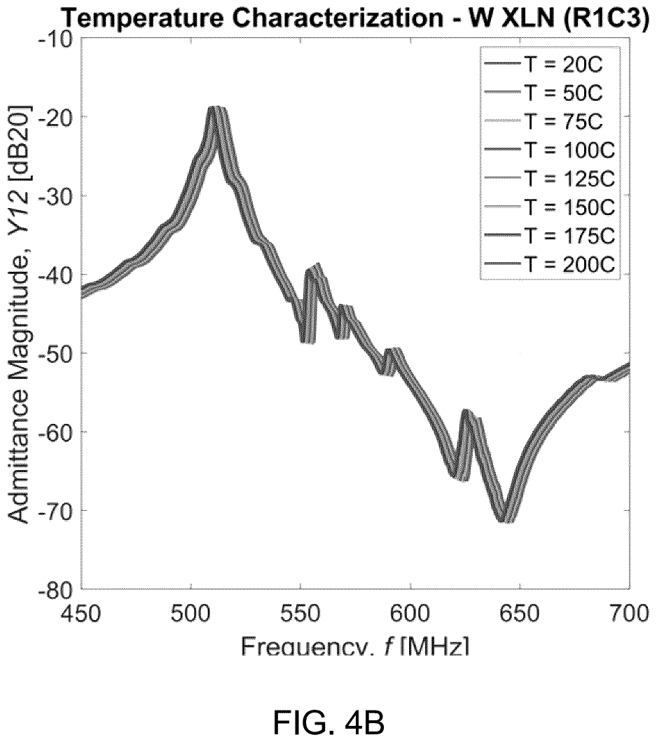

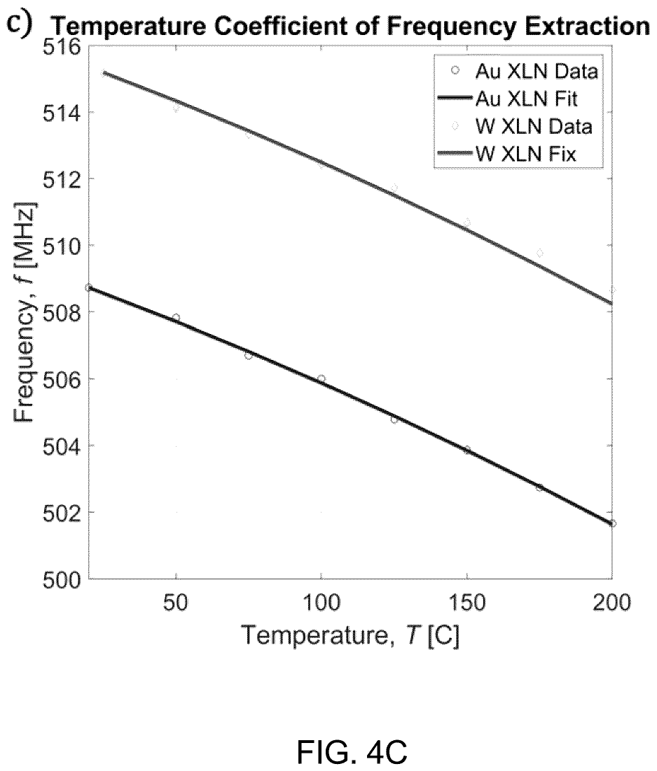

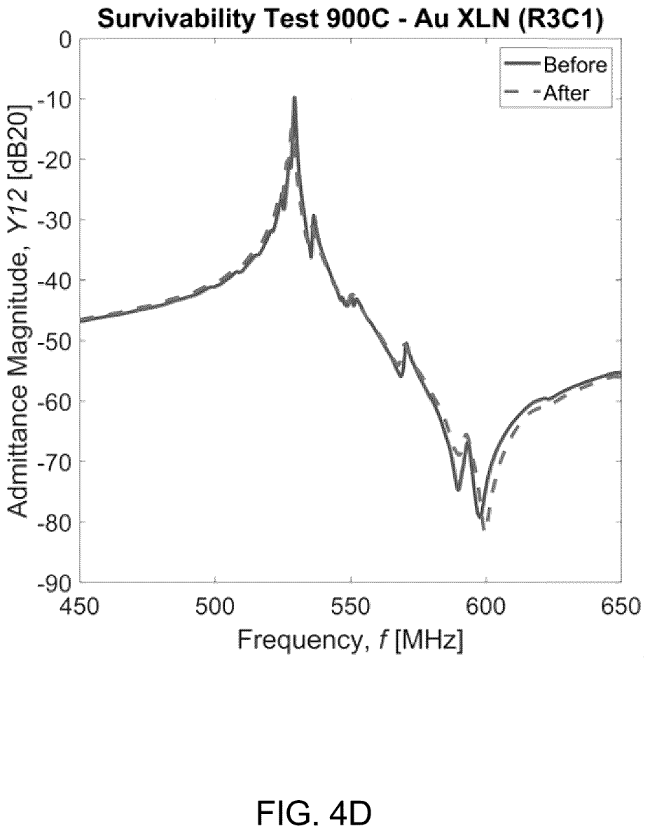

In order to characterize the temperature behavior of the devices, the chip was heated using a hot plate built into the probe station; the response was tracked via direct RF probing while the temperature was linearly increased with steps of 25° C. in the range 20-200° C. All measurements were carried out in steady state conditions. The converted admittances for both Au and W devices are shown in FIGS. 4A & 4B respectively. For both devices, the first order Temperature Coefficient of Frequency (TCF) was extrapolated according to the equation:

$$\frac{Δ f}{{f}_{0}} = {TCF}_{1} \cdot ( T - {T}_{0} ) \qquad ( 1 )$$

and found to be equal to −65 ppm/K and −67 ppm/k for the Au and W devices respectively as shown in FIG. 4C; values that are consistent with literature [11]. The small discrepancy may be attributed to the different thermal properties of the metals.

In order to test the ultimate device resistance, the chip was exposed to a direct butane flame (rated at 900° C.) for a time of 60s. The before/after comparison shown in FIG. 4D indicates negligible difference in the response of the resonator.

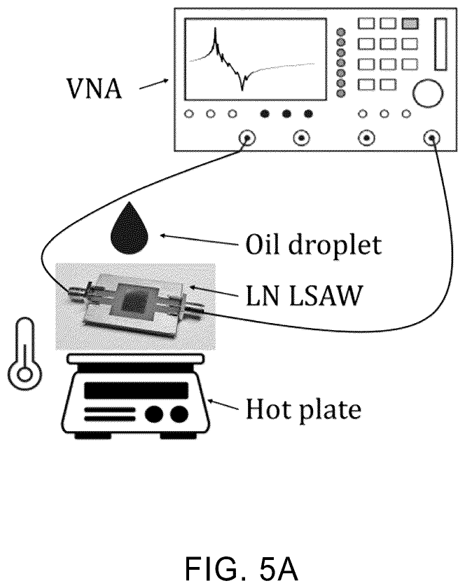

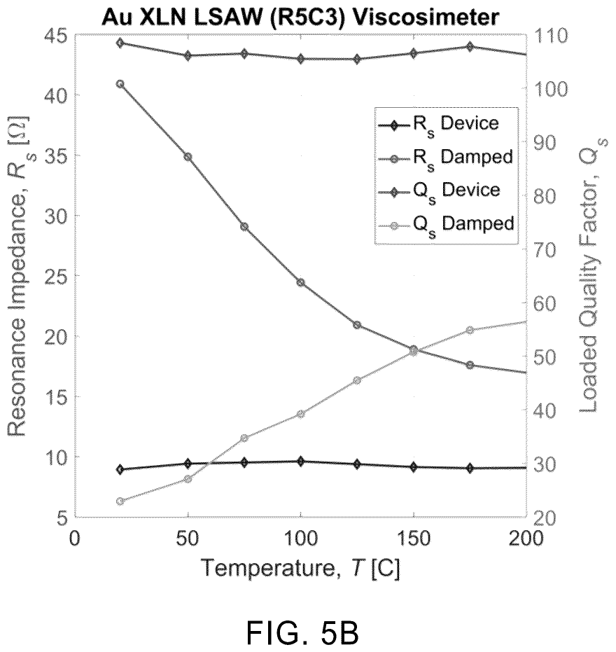

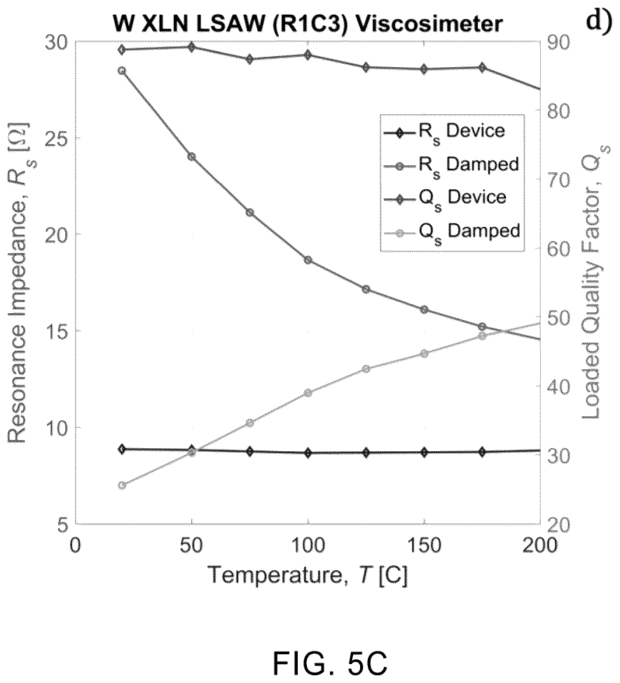

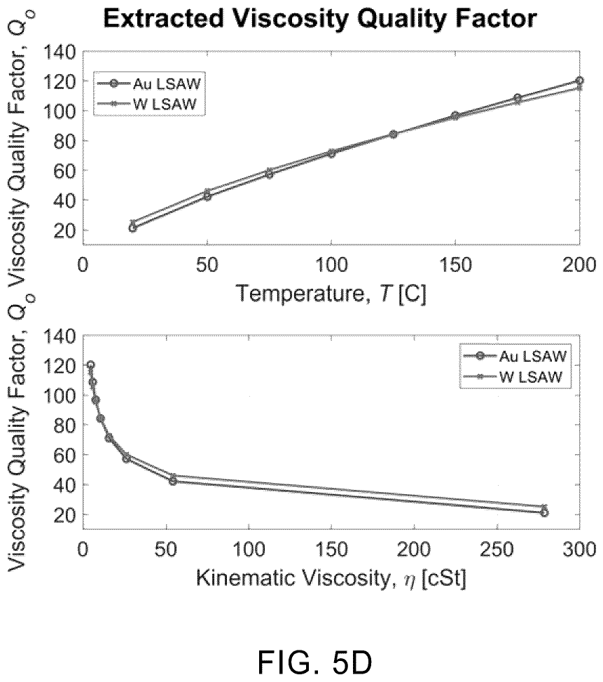

As shown in FIG. 5A, the chip was bonded to an FR4 board and heated on a hot plate to test the loaded performance. Upon cooling down, a droplet of Fombling Oil 25/6 was applied and the temperature was raised to 200° C. The FR4 board was connected to a Vector Network Analyzer and probed in steady-state conditions.

The quality factor can be expressed as follows:

$$\frac{1}{Q} = \frac{1}{{Q}_{I}} + \frac{1}{{Q}_{η}} \qquad ( 2 )$$

where Q_{I} represents the intrinsic losses mechanisms inherent to the device and Q_{η} the viscous damping imparted by the fluid. Viscous damping is a complex phenomenon to model for solidly mounted resonators; however to a first approximation it may be considered that Qₑₜₐ∝1/η [12]. Additionally, the rheological properties of Fomblin Oil 25/6, show an inverse proportionality relationship between its kinetic viscosity and temperature, η∝1/T [13]. Combining these two equations, a linear relationship between viscous quality factor and temperature is expected. Therefore, by tracking the shift in the device response it is possible to infer both the temperature of the surrounding environment and the viscosity of the fluid in which it is immersed.

FIGS. 5B & 5C show the extracted quality factors and impedances at resonance for both the Au and W devices as a function of temperature. The overall reduced quality factors are due to the long wire bonds that were necessarily installed for the testing. By applying Eq. 2, the viscosity quality factor as function of temperature and kinetic viscosity is calculated. The linear trend Q∝T is clearly visible in FIG. 5D. The extracted Q/are consistent between both the Au and W devices, therefore the two measurements validated each other.

These techniques and experiments successfully demonstrated a high figure of merit with stable response SH₀ lithium niobate LSAW, employing gold and tungsten as electrodes, and its possible application in harsh environments. Experimental results confirm the device promising performance, while leaving room for improvements. Higher temperature characterization is fundamental to unsure the device integrability with existing SiC platforms. Additionally, the study could be extended to other lithium niobate cuts, with improved designs to suppress unwanted in-band spurious modes to further boost quality factor and electromechanical coupling as to improve overall performance and sensitivity.

The viscosimeter's ability to be operate at high-temperatures (i.e., 900° C. or higher) and other harsh environments provides for use in industrial applications such as at a refinery, a chemical processing plant, in internal combustion engines, jet engines, rocket combustion chambers, and systems with high pressure and/or high temperature hydraulic systems. The viscosimeter can be used in harsh environment applications to measure temperature and viscosity of fluids, such as fuels and combustion gases of internal combustion engines for cars and trucks, jet engines, rocket engines, generators, and ship propulsion engines. The viscosimeter also can be used to measure or monitor the viscosity of an oil or lubricant, such as motor oil, hydraulic fluid, fuel, or transmission fluid, brake fluid, or a lubricant for machinery. In some applications, the viscosity measurement may be used to measure changes in the viscosity of the fluid (or gas) and detect contamination of the fluid (e.g., oil), as the accumulation of contaminants or chemical breakdown products may alter the viscosity of a fluid, such as a lubricant, engine oil, or brake fluid. Additionally, due to its micron-range size, robustness, and stability, the viscosimeter also can be used in low temperature applications such as biomedical applications, e.g., for body fluid temperature and/or viscosity measurements of blood, urine, or mucous secretions such as bronchial secretions.

As used herein, “consisting essentially of” allows the inclusion of materials or steps that do not materially affect the basic and novel characteristics of the claim. Any recitation herein of the term “comprising”, particularly in a listing of components of a composition or elements of a device, constitutes inclusion of alternative embodiments in which “comprising” is replaced with “consisting essentially of” or “consisting of”.

While the present invention has been described in conjunction with certain preferred embodiments, one of ordinary skill, after reading the foregoing specification, will be able to effect various changes, substitutions of equivalents, and other alterations to the compositions and methods set forth herein.

### REFERENCES

[1] H.-D. Ngo, P. Mackowiack, N. Grabbert, T. Weiland, X. Hu, M. Schneider-Ramelow, O. Ehrmann, and K.-D. Lang, “The roadmap for development of piezoresistive micro mechanical sensors for harsh environment applications,” in 2017 Eleventh International Conference on Sensing Technology (ICST), pp. 1-6, 2017.
[2] P. French, G. Krijnen, and F. Roozeboom, “Precision in harsh environments,” Microsystems & nanoengineering, vol. 2, no. 1, pp. 1-12, 2016.
[3] M. R. Werner and W. R. Fahrner, “Review on materials, microsensors, systems and devices for high-temperature and harsh-environment applications,” IEEE Transactions on Industrial Electronics, vol. 48, no. 2, pp. 249-257, 2001.
[4] B. Liu, X. Chen, H. Cai, M. M. Ali, X. Tian, L. Tao, Y. Yang, and T. Ren, “Surface acoustic wave devices for sensor applications,” Journal of semiconductors, vol. 37, no. 2, p. 021001, 2016.
[5] J. Mrosk, L. Berger, C. Ettl, H.-J. Fecht, G. Fischerauer, and A. Dommann, “Materials issues of saw sensors for high-temperature applications,” IEEE Transactions on Industrial Electronics, vol. 48, no. 2, pp. 258-264, 2001.
[6] P. G. Neudeck, “Progress in silicon carbide semiconductor electronics technology,” Journal of Electronic Materials.
[7] D. G. Senesky, B. Jamshidi, K. B. Cheng, and A. P. Pisano, “Harsh environment silicon carbide sensors for health and performance monitoring of aerospace systems: A review,” IEEE Sensors Journal, vol. 9, no. 11, pp. 1472-1478, 2009.
[8] G. Smolenskii, N. Krainik, N. Khuchua, V. Zhdanova, and I. Mylnikova, “The curie temperature of linbo3,” Physica status solidi (b), vol. 13, no. 2, pp. 309-314, 1966.
[9] R. H. Olsson III, K. Hattar, S. J. Homeijer, M. Wiwi, M. Eichenfield, D. W. Branch, M. S. Baker, J. Nguyen, B. Clark, T. Bauer, et al., “A high electromechanical coupling coefficient sh0 lamb wave lithium niobate micromechanical resonator and a method for fabrication,” Sensors and Actuators A: Physical, vol. 209, pp. 183-190, 2014.
[10] L. Colombo, G. Giribaldi, R. Tetro, J. Guida, W. Gubinelli, L. Spagnuolo, N. Maietta, S. Ghosh, and M. Rinaldi, “Characterization of acoustic losses in interdigitated vhf to mmwave piezoelectric m/nems resonators,” arXiv preprint arXiv:2406.07784, 2024.
[11] J. Mrosk, L. Berger, C. Ettl, H.-J. Fecht, G. Fischerauer, and A. Dommann, “Materials issues of saw sensors for high-temperature applications,” IEEE Transactions on Industrial Electronics, vol. 48, no. 2, pp. 258-264, 2001.
[12] A. K. Pandey, “Analytical, numerical and experimental studies of fluid damping in mems devices,” Indian Institute of Science, 2007.
[13] Datasheets.com, “Fomblin y Ivac 25/6,” 2017.

What is claimed is:

1. A heat-resistant surface acoustic wave (SAW) resonator-based viscosimeter comprising:
a piezoelectric layer comprising a piezoelectric material;
a pair of interdigitated electrodes disposed on an upper surface of the piezoelectric layer, the electrodes comprising a heat-resistant conductive metal, each of said electrodes linked via a heat-resistant conductive pathway to a contact pad;
wherein the viscosimeter supports a surface acoustic wave (SAW) mode of resonance;
wherein the viscosimeter, when in contact with a fluid and connected via the contact pads to a readout circuit, provides a signal indicating viscosity of the fluid at a temperature of the fluid of at least about 500° C.

2. The viscosimeter of claim 1, wherein the piezoelectric layer is a bulk solid or comprises a cavity below the upper surface of the piezoelectric layer.

3. The viscosimeter of claim 1, further comprising a substrate, wherein a lower surface of the piezoelectric layer opposite the electrodes is disposed on a surface of the substrate.

4. The viscosimeter of claim 1, wherein the substrate is solid or comprises a cavity below the piezoelectric layer.

5. The viscosimeter of claim 1, wherein the viscosimeter comprises a cavity in the piezoelectric layer or in the substrate, and wherein a portion of the piezoelectric layer and/or the substrate layer above the cavity is released.

6. The viscosimeter of claim 1, wherein the piezoelectric material is selected from the group consisting of lithium niobate, lithium tantalate, aluminum nitride, scandium doped aluminum nitride having a scandium content from about 1 mol % to about 45 mol %, and combinations thereof.

7. The viscosimeter of claim 1, wherein the piezoelectric material has a piezoelectric coefficient of at least about 0.19 C/m² and/or a Curie temperature of at least about 610° C.

8. The viscosimeter of claim 1, wherein the electrodes comprise a metal or metal alloy selected from the group consisting of gold, tungsten, platinum, titanium, iridium, chromium, copper, and combinations thereof, wherein the metal or metal alloy has a melting temperature of at least about 500° C.

9. The viscosimeter of claim 1, wherein the fluid is a liquid or a gas.

10. The viscosimeter of claim 1, wherein the SAW resonance mode comprises Rayliegh waves, Lamb waves, Love waves, Sezawa waves, or an overtone thereof.

11. The viscosimeter of claim 1, wherein a quality factor of the viscosimeter at resonance or antiresonance exhibits dependence on temperature and viscosity of said fluid.

12. The viscosimeter of claim 11, wherein said dependence on temperature is characterized by a temperature coefficient of frequency of from about −10 to about +10 ppm/K.

13. The viscosimeter of claim 11, wherein said dependence on viscosity is characterized by a viscoelastic damping quality factor of at least about 1000.

14. The viscosimeter of claim 1, wherein the viscosimeter has a quality factor of at least about 1000 in the absence of fluid and at about 15 to 40° C.

15. The viscosimeter of claim 1, wherein the viscosimeter has a power handling capacity of up to at least 15 dBm.

16. The viscosimeter of claim 1, further comprising a readout circuit connected via the contact pads to the pair of interdigitated electrodes and a battery driving the circuit.

17. The viscosimeter of claim 16, further comprising a wired or wireless transmitter or transponder, or a display.

18. A system for detecting viscosity, comprising:
at least one processor;
at least one memory;
a microcontroller; and
one or more viscosimeters of claim 1 deployed in an environment having a viscosity of interest.

19. A method for determining a viscosity of a fluid, the method comprising:
(a) providing a viscosimeter of claim 1, wherein the viscosimeter contacts said fluid;
(b) establishing an AC signal across the interdigitated electrodes of the viscosimeter, whereby a SAW resonance is produced in the viscosimeter;
(c) measuring a resonance frequency of the viscosimeter;
viscosity of the fluid using the viscosimeter or the system; and
(d) determining said viscosity based on the resonance frequency.

20. The method of claim 19, further comprising:
measuring a temperature of the fluid using the viscosimeter.

21. The method of claim 19 wherein the temperature of the fluid is at least 500° C.

22. The method of claim 19, wherein the viscosimeter is disposed in an internal combustion engine, hydraulic machine, chemical processing plant or refinery, oil or gas drilling equipment, or rocket engine.

23. The method of claim 19, wherein the fluid is an oil, lubricant, hydraulic fluid, drilling fluid, fuel, transmission fluid, or brake fluid.

24. The method of claim 19, further comprising:
comparing the measured viscosity to reference viscosity data for said fluid; and
determining a state of contamination for the fluid.
